(19) United States
(12) Patent Application Publication
(10) Pub. No.: US 2015/0140213 A1
(43) Pub. Date: May 21, 2015

(54) PRODUCTION OF GLANCING ANGLE DEPOSITED FILMS

(71) Applicants: The Governors of the University of Alberta, Edmonton (CA); National Research Council of Canada, Ottawa (CA); Micralyne Inc., Edmonton (CA)

(72) Inventors: Michael Thomas Taschuk, Edmonton (CA); Michael Julian Brett, Edmonton (CA); Andy Christopher van Popta, Edmonton (CA); Peter Charles Philip Hrudey, Edmonton (CA)

(21) Appl. No.: 14/495,608

(22) Filed: Sep. 24, 2014

Related U.S. Application Data
(60) Provisional application No. 61/881,815, filed on Sep. 24, 2013.

(51) Int. Cl. C23C 14/22

(52) U.S. Cl. CPC C23C 14/22
USPC 427/255.5; 118/722

(57) ABSTRACT

Method and apparatus for producing glancing angle deposited thin films. There is a source of collimated vapour flux, the source of collimated vapour flux having a deposition field; and a travelling substrate disposed within the deposition field of the source of collimated vapour flux, the collimated vapor flux being collimated at a defined non-zero angle to a normal to the travelling substrate.

### CROSS-REFERENCE TO RELATED APPLICATIONS

This application claims the benefit under 35 USC 119(e) of U.S. provisional application No. 61/881,815 filed Sep. 24, 2013.

### FIELD

Processes and apparatus for producing glancing angle deposited thin films.

### BACKGROUND

Glancing angle deposited (GLAD) thin films are known from U.S. Pat. Nos. 6,248,422, 6,206,065 and 5,866,204. The GLAD patents focus on the possible structures and methods for controlling them, as does the scientific work which followed. There are a few patents which describe fabrication methods, but to the inventors' knowledge, all use multiple wafers in a single chamber. This approach limits the number of substrates that can be processed, adversely impacting the commercialization of the GLAD process.

### SUMMARY

In an embodiment, there is disclosed an apparatus for producing glancing angle deposited thin films, the apparatus comprising a source of collimated vapour flux, the source of collimated vapour flux having a deposition field; and a travelling substrate disposed within the deposition field of the source of collimated vapour flux, the collimated vapor flux being collimated at a defined non-zero angle to a normal to the travelling substrate. In an embodiment, there is disclosed a method of producing glancing angle deposited thin films, the method comprising collimating a vapour flux; and exposing a travelling substrate to the collimated vapour flux, the vapor flux being collimated at a non-zero angle to a normal to the substrate. The source of collimated vapour flux may comprise a material having angled channels, for example a louvre. The travelling substrate may comprise an endless conveyor or a discrete substrate on an endless conveyor. Collimating the vapour flux may comprise selecting a defined angle of vapour flux by passing the vapour flux through a material having angled channels.

### BRIEF DESCRIPTION OF THE FIGURES

Embodiments of the production method and apparatus will now be described with reference to the figures, by way of example, in which like reference characters denote like elements, and in which:

FIG. 1 shows a schematic view of a substrate within a deposition field indicating the geometric parameters of a GLAD film, with the substrate shown in top view and side view.

FIG. 2 shows views of a 2D louvre used to produce slanted posts. The individual channels can be in any orientation, allowing arbitrary selection of the physical vapour deposition flux as a function of position along the louvre.

FIG. 3 shows a schematic view of an embodiment of an apparatus for producing glancing angle deposited thin films in which a 2D louvre is applied to a linear PVD source.

FIG. 4 shows a schematic view of the growth of a chevron GLAD film. The 2D louvre has two zones which select different components of the isotropic physical vapour deposition flux. The web travels from the bottom of the figure to the top of the figure. Within the first zone (A), the voids in the 2D louvre select flux which is incident on the travelling web from the right; in the second zone (B), the voids in the 2D loure select flux incident on the travelling web from the left. The resulting film is a chevron, shown in the insets at different points of the film's growth.

FIG. 5 shows a schematic view of the production of a square spiral. The 2D louvre has four zones which select different components of the isotropic PVD flux. The travelling substrates travel from the bottom of the figure to the top of the figure. Acting in alphabetic order, this 2D louvre produces one period of a square spiral. The selection of a particular flux orientation is shown for each growth phase and the resulting film growth is shown in the insets.

FIG. 6 shows an arrow convention for showing larger 2D louvres.

FIG. 7 shows 2D louvres for producing five of the canonical GLAD films, shown using the arrow convention. Each 2D louvre segment shown can be placed in an arbitrary sequence to generate a large set of GLAD films, or broken up into the individual growth phases to generate any possible GLAD film.

FIG. 8 shows an implementation of Phi-sweep using the 2D louvres. The insets show the details of the open slats for producing a Phi-sweep distribution of vapour flux material.

### DETAILED DESCRIPTION

Immaterial modifications may be made to the embodiments described here without departing from what is covered by the claims. In the claims, the word “comprising” is used in its inclusive sense and does not exclude other elements being present. The indefinite articles “a” and “an” before a claim feature do not exclude more than one of the feature being present. Each one of the individual features described here may be used in one or more embodiments and is not, by virtue only of being described here, to be construed as essential to all embodiments as defined by the claims.

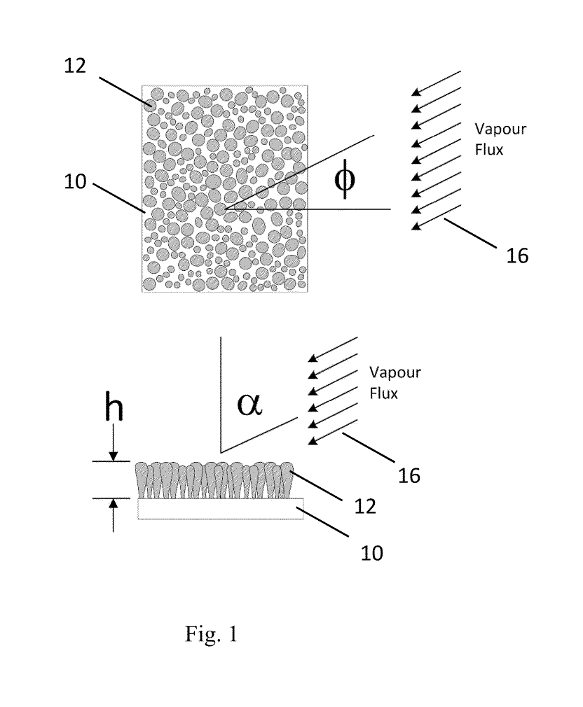

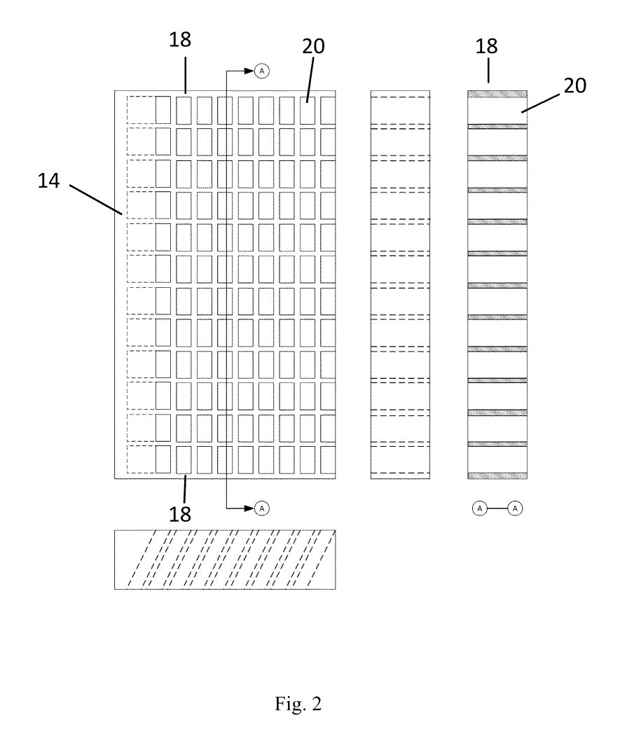

There is disclosed a roll-to-roll approach modified for GLAD films, which has been the basis for commercial scale thin film processes such as potato chip bags, magnetic tape, film production, and others. To produce precise nanostructured films 12, the GLAD process dynamically controls substrate 10 orientation in time. As shown in FIG. 1, GLAD film can be thought of as tracing a trajectory through a four dimensional space defined by three geometrical parameters: film height, vapour source altitude and vapour source azimuth, and one material parameter defining the composition of the physical vapour flux plume. The mechanical apparatus expresses this trajectory in a form suitable for roll-to-roll processing. As shown in FIG. 2, two-dimensional louvres 14 are placed between evaporation or sputtering source (s) (not shown) and a travelling substrate 10 (or web) on which the GLAD film 12 will be deposited. The louvres 14 in combination with the vapour sources form a source of collimated vapour, required for glancing angle deposition, at a defined non-zero angle to a normal to the substrate 10. The vapour sources emit vapour 16 at a range of angles. The louvres 14 select the defined angle for deposition in relation to a normal to the substrate 10 (altitude) and azimuth. The louvres 14 may be formed by spaced parallel slats 18 that extend linearly much more than the spacing between the slats. Other ways to form the louvres 14 may be used. The louvres 14 define channels 20 with confining walls that are sufficiently long that vapour 16 not at the desired angle impacts the walls of the channels 20. The channels 20 may be bored in a material, or formed by intersecting webs of material, or by parallel slats, or any other way to form slanted channels 20.

The travelling substrate 10 is positioned so that in operation it is exposed to the vapour flux 16 to allow the vapour 16 to be deposited on the substrate 10. The region in which the vapour flux 16 remains collimated so that it may be deposited on the substrate 10 is referred to here as the deposition field of the vapour source. For any given strength of vapour generation and type of vapour source, the deposition field can be easily calculated by an operator of the apparatus. In all the figures shown here, the travelling substrate 10 is within the deposition field of the vapour sources. The apparatus will normally be confined within a low pressure chamber, with pressures suitable to prevent or reduce undesirable scattering of the vapour 16. The effect of scattering is to reduce the definition of the structures grown on the substrate 10. The amount of permitted scattering is therefore dependent on the required definition in the structures. The operator may adjust the pressure of the pressure chamber accordingly. Thus, processes described here should be carried out in conditions in which the vapour flux 16 arrives at the substrate 10 in approximately a straight line. For this reason, it is preferred that the process be carried out under conditions approximating a vacuum, for example at less than 0.13N/m² (10⁻³ torr), for example at 1.3×10⁻⁴N/m² (10⁻⁶ torr).

The substrate 10 may be any solid material on which a vapour 16 may be deposited, and will depend on the application. The substrates 10 include, but are not limited to, flexible sheets of metal or plastic, or discrete rigid substrates such as silicon or glass substrates. The material to be deposited may be any material for which conditions are achievable to support vapor generation and deposition of the vaporized material on the substrate 10. In some cases, this may require cooling or heating of the substrate 10. To assist in bonding one vaporized material to another, an intervening layer may be first deposited, as for example using a chromium intermediate layer to bond gold to amorphous silicon dioxide (glass). In addition, the material used should have a sticking co-efficient of at least about 0.9 to enable the formation of distinct structures.

The travelling substrate 10 may travel by moving linearly or in an arc, such as when on the surface of a rotating element or spirally moving element.

A GLAD film's growth geometry can be described by a trajectory through a three dimensional space defined by height, the altitude of the vapour flux 16 (typically referred to as a in the GLAD literature), and the azimuth of the vapour flux 16 (typically referred to as Φ in GLAD literature). In addition to the geometry, a parameter which identifies the growth material is defined. The geometric parameters are shown in FIG. 1.

Height: h, units of nm

Vapour Flux Altitude: α, units of degrees

Vapour Flux Azimuth: φ, units of degrees

Material: M, unitless

Each growth phase of a GLAD film can be described by a single set of these four numbers. The resolution required depends on the particular desired geometry. For simple films, such as slanted posts, a single set. More complex films, such as a phi-sweep slow corner square spiral can be made up with hundreds of sets, making up a deposition algorithm. Any possible GLAD film can be described by a deposition algorithm, and a R2R system will be required to achieve algorithms to deposit any GLAD film.

A R2R web or endless conveyor moves at a constant speed powered by a motor on one or both rolls. Therefore, to accommodate the full control needed for a GLAD film deposition in a R2R system, it is necessary to relate the growth rate on the travelling web to GLAD geometry and the conditions imposed by a 2D louvre. For one point on the surface of and physical vapour deposition source, the rate at the substrate 10 is given by

$${R}_{substrate} = {R}_{source} \frac{{cos}^{n} ( α )}{{R}^{2}} \qquad [ 1 ]$$

where R_{substrate} is the deposition rate at the substrate 10, R_{source} is the physical vapour emission rate at the source, R is the distance between the infinitesimal point on the substrate 10 and the infinitesimal point on the travelling web, a is the altitude of the infinitesimal point on the substrate 10 measured from the travelling web, and n is a parameter describing the shape of the physical vapour emission plume.

The height for a growth phase of a GLAD film is defined by

$$h = {R}_{substrate} {T}_{phase} = \frac{{R}_{substrate} {ℒ}_{phase}}{{V}_{web}} \qquad [ 2 ]$$

where Tₚₕₐₛₑ is the time required for a given phase, Lₚₕₐₛₑ is the length required for a given phase, and V_{web} is the speed of the travelling substrate(s) 10. For a single growth phase, the distance required for a single phase is then given by

$${ℒ}_{phase} = \frac{{hR}^{2} {V}_{web}}{{R}_{source} {cos}^{n} ( α )} . \qquad [ 3 ]$$

For any given growth phase, the 2D louvres 14 will impose the correct altitude and azimuth. Details of this process and worked examples are given in the next section. A final important aspect is that the travelling substrate 10 can travel without impinging vapour flux 16 for arbitrary periods, as necessary to achieve the necessary changes in vapour flux direction in the 2D louvre 14.

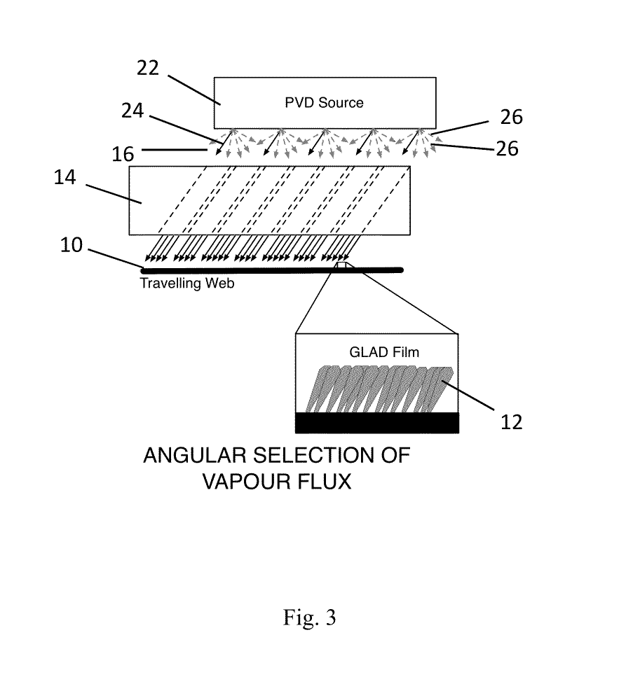

This section introduces the 2D louvres 14, and the configurations required to produce GLAD structures. FIG. 3 shows the production of a slanted post GLAD film. The PVD source 22 emits vapour flux 16 with no preferential direction. The 2D louvre 14 selects one angle 24 and rejects the unwanted vapour flux 26. The selected flux is collimated and at a designed angle when it intersects the travelling web 10. In this case the physical vapour source is linear, extending into the page. In general, such vapour sources emit vapour flux 16 in an uncontrolled distribution, shown by the dashed arrows. The 2D louvre shown in FIG. 2 will only permit vapour flux 16 at the correct altitude and phi, selecting the solid arrows 24 emitted from the vapour source 22. Given a sufficiently low base pressure, over the entire source 22 the louvre 14 produces a collimated vapour flux, satisfying the requirements for GLAD deposition. Since the 2D louvre 14 shown in FIG. 2 selects only a single α and Φ, slanted posts are produced on the travelling substrate 10.

The film deposit can be built up to any desired height by extending the length of the 2D louvre 14, or by performing multiple passes under the same 2D louvre 14, or by moving the travelling substrate 10 in a spiral under multiple 2D louvres.

Films of multiple materials can be produced by changing composition of the physical vapour source material, using multiple sources with different source material composition or by replacing source material and depositing additional material.

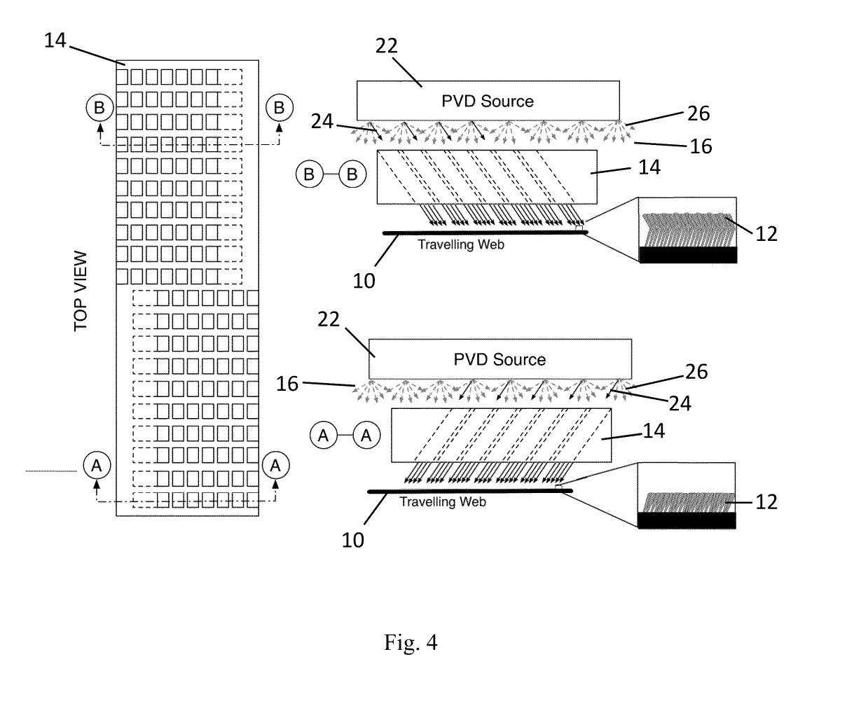

FIG. 4 shows the production of a chevron or ‘zig-zag’ film. In this case, the holes in the 2D louvre 14 change their orientation, corresponding to transition between the two growth phases. In this case, the travelling substrate 10 travels from bottom to top. At section A-A, the deposited film 12 forms a slanted post inclined to the right side. As the travelling substrate 10 travels upwards, the orientation of the incoming vapour flux 16 flips sides, growing a slanted post inclined to the left side. When the travelling substrate 10 reaches section B-B, the deposited film 12 has started to form a chevron structure.

To adjust the pitch of the chevron, the length of each section should be adjusted according to the equations outlined above. As the distance Lₚₕₐₛₑ is decreased (or V_{web} is increased), serial bi-deposition films will be produced.

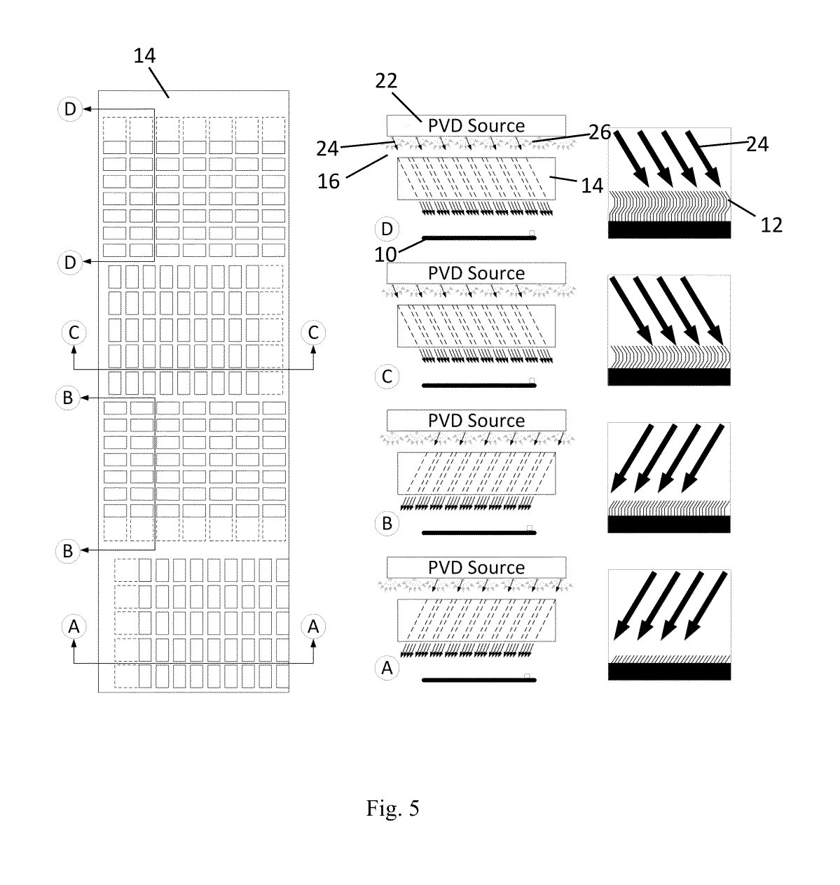

Slightly more complicated than the chevron, the square spiral can also be produced using the 2D louvre shown in FIG. 5.

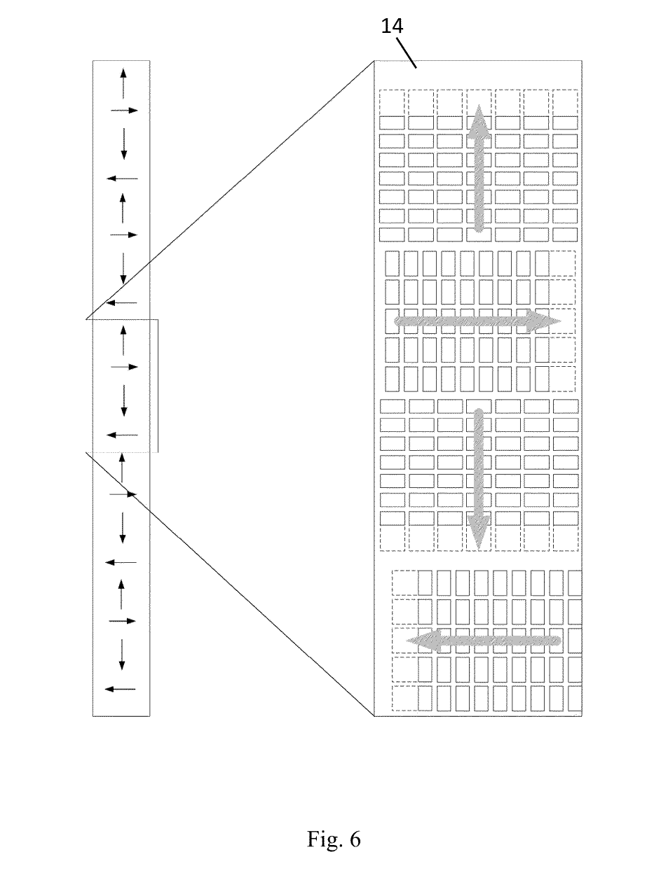

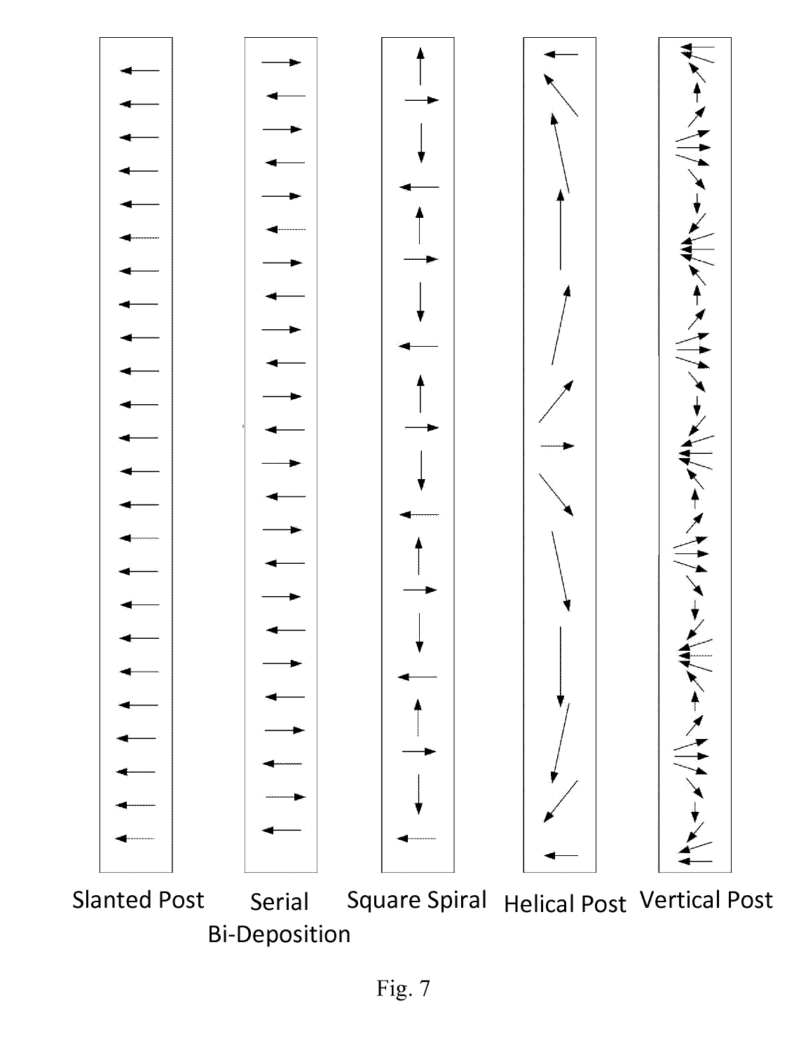

To reduce figure complexity, going forward the individual growth phases will be denoted using an arrow for the helical, vertical post, and supersets of the canonical GLAD films shown here. This approach is shown in FIG. 6 for the square spiral case from FIG. 5. FIG. 7 shows 2D Louvres for producing five of the canonical GLAD films, shown using the arrow convention. Each 2D Louvre segment shown can be placed in an arbitrary sequence to generate a large set of GLAD films, or broken up into the individual growth phases to generate any possible GLAD film.

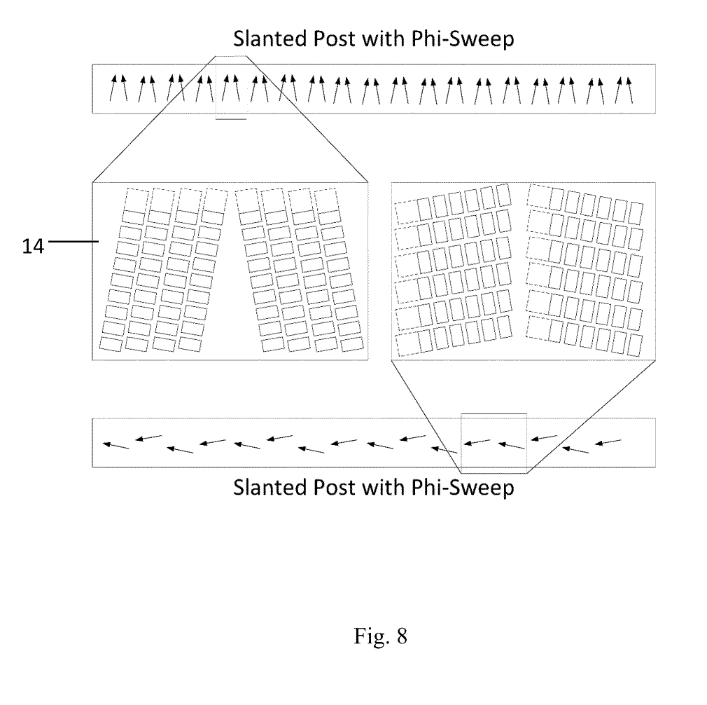

Advanced GLAD deposition algorithms, such as Phi-sweep, are possible using this invention. FIG. 8 shows two of the possible configurations for Phi-sweep slanted posts, parallel and perpendicular to the direction of travel of the travelling substrate 10.

This technology can be used with any of the following source types: E-beam evaporation, Ion-beam assisted deposition, Sputtering, Thermal evaporation, Molecular beams.

A linear source can be synthesized by arranging any of these source types, or any combination thereof, into a line to produce vapour flux 16. Multiple materials can be deposited in a single deposition by using different sources or source material.

The 2D louvres 14 can be used in any configuration relative to the source, including above, below and to the side. Any substrate type can be used in this technology, including conventional roll-to-roll webs and discrete substrates. A discrete substrate may be carried by a conveyor such as a travelling conveyor. The conveyor could be any conventional conveyor used in industrial processing and could be an endless conveyor.

The 2D louvre technology can be used with any material compatible with any of the evaporation technologies listed here: E-beam evaporation, Ion-beam assisted deposition, Sputtering, Thermal evaporation, Molecular beams, including, but not limited to those listed here:

| Elemental | Inorganic | Organic |
|---|---|---|
| Aluminum | Al2O3 | Alq3 |
| Carbon | As2S3 | C60 |
| Chromium | CaF2 | CuPc |
| Cobalt | CeO2 | Parylene C |
| Copper | CrN | Pentacene |
| Germanium | GeSbSn | PPX |
| Iron | HfO2 | Znq2 |
| Magnesium | InN | |
| Nickel | ITO | |
| Palladium | MgF2 | |
| Platinum | Nb2O5 | |
| Ruthenium | SiO | |
| Selenium | SiO2 | |
| Silicon | Ta2O5 | |
| Silver | TiO2 | |
| Tantalum | TiZrV | |
| Tellurium | WO3 | |
| Titanium | Y2O3: Eu | |
| Tungsten | YSZ | |
| | ZnS | |
| | Zr65Al7.5Cu27.5 | |
| | ZrO2 | |

What is claimed is:

1. An apparatus for producing glancing angle deposited thin films, the apparatus comprising:
a source of collimated vapour flux, the source of collimated vapour flux having a deposition field; and
a travelling substrate disposed within the deposition field of the source of collimated vapour flux, the collimated vapor flux being collimated at a defined non-zero angle to a normal to the travelling substrate.

2. The apparatus of claim 1 in which the source of collimated vapour flux comprises a material having angled channels.

3. The apparatus of claim 2 in which the source of collimated vapour flux comprises a louvre.

4. The apparatus of claim 3 in which the travelling substrate comprises an endless conveyor.

5. The apparatus of claim 1 in which the travelling substrate comprises an endless conveyor.

6. The apparatus of claim 5 in which the travelling substrate comprises a discrete substrate on an endless conveyor.

7. A method of producing glancing angle deposited thin films, the method comprising:
collimating a vapour flux; and
exposing a travelling substrate to the collimated vapour flux, the vapor flux being collimated at a non-zero angle to a normal to the substrate.

8. The method of claim 7 in which collimating the vapour flux comprises selecting a defined angle of vapour flux by passing the vapour flux through a material having angled channels.

9. The method of claim 8 in which the material having angled channels comprises a louvre.

10. The method of claim 8 in which the travelling substrate comprises an endless conveyor.

11. The method of claim 10 in which the travelling substrate comprises a discrete substrate on an endless conveyor.
